(19) United States
(12) Patent Application Publication
(10) Pub. No.: US 2011/0073182 A1
(43) Pub. Date: Mar. 31, 2011

(54) GLASS PLATE FOR A SOLAR UNIT, AND GLASS COMPOSITION

(75) Inventors: Shona Taylor, Ormskirk (GB); Neil McSporran, Liverpool (GB)

(73) Assignee: PILKINGTON GROUP LIMITED

(21) Appl. No.: 12/737,069

(22) PCT Filed: Jun. 9, 2009
(86) PCT No.: PCT/GB2009/050640

§ 371 Date: Dec. 6, 2010

(30) Foreign Application Priority Data
Jun. 9, 2008 (GB) 0810525.6

(51) Int. Cl. H01L 31/02; C03C 3/087; C03C 3/078; C03C 3/04

(52) U.S. Cl. 136/259; 501/70; 501/72; 501/53; 428/220

(57) ABSTRACT

A solar unit glass plate having a composition comprising the following constituents, the amounts of which are expressed as percentages by weight: SiO₂ 60-75%; Al₂O₃ 0-5%; Na₂O 10-18%; K₂O 0-5%; CaO 0-11%; MgO 0-5%; SO₃ 0-1%; Fe₂O₃<0.15%; and one or both of: SrO 0-15% and BaO 0-15%, with the proviso that the summed amount of SrO and BaO is greater than 1%. Also a glass plate for use as a cover plate or backing plate for a solar unit, the plate having a composition comprising the following constituents, similarly expressed: SiO₂ 65-74%; Al₂O₃ 0-3%; Na₂O 12-15%; K₂O 0-2%; CaO 0-11%; MgO 0-2%; SO₃ 0-1%; Fe₂O₃ (total iron)<0.1%; and one or both of: SrO 2-10% and BaO 1.5-10%, with the proviso that the summed amount of SrO and BaO is greater than 2%.

The present invention relates to an improved glass plate for a solar unit, and more especially to a glass composition for the plate. This composition exhibits high transmission across the wavelength range over which the solar material (e.g. photovoltaic material) comprised in such a unit is operational.

In this specification, the term “solar unit” means any and/or all of the following: an individual photovoltaic cell (also known in the art as a solar cell), a module comprising multiple photovoltaic cells, a solar mirror, a solar lens and a solar thermal system. A solar mirror is a mirror which reflects and/or focuses electromagnetic radiation from the sun (e.g. infrared (IR), visible and/or ultraviolet (UV) radiation) onto a device that is capable of collecting and/or generating energy, such as heat or electricity. Such a mirror may also be known as a concentrator. A solar thermal system may comprise an array of heat-absorbing fluid-filled tubes, or an equivalent solar heating system, protected by a glass cover plate.

In recent years, the demand for alternative sources of energy (that is, alternative to fossil fuels) has grown steadily. One of the greatest alternative sources of energy is the sun, and there are numerous techniques and devices available to harness this energy, including the above-mentioned solar heat mirror concentrator systems, solar water heaters and photovoltaic cells or modules.

A photovoltaic solar unit typically comprises a glass cover plate, through which solar electromagnetic radiation passes to one or more underlying layers of solar material, which in this context means material which produces electricity under the influence of visible light, IR and UV radiation, (commonly known as photovoltaic material). A backing plate or substrate, which may also be made of glass, is usually included to provide mechanical stability to the unit.

A solar unit in the form of a mirror typically comprises a highly transmitting glass substrate having a layer of a reflective metal such as silver on its rear or second surface (i.e. the surface which is further from the sun, compared with the surface on which light is incident). To protect the mirror from factors such as atmospheric pollution, increased moisture levels, scratching and abrasion, which may reduce its reflectivity, it is known to provide a layer containing another metal, such as copper or tin, over the silver layer to retard tarnishing. Furthermore it is known to protect the further metal layer with one or more layers of a paint to increase its physical and chemical durability.

In the context of a solar unit in the form of a solar thermal system, solar material means the heat-absorbing fluid-filled tube array or equivalent.

A number of different photovoltaic units are known in the art, which fall into one of three broad types depending on the nature of the photovoltaic material employed—crystalline or wafer, thin film coating or organic. Crystalline photovoltaic materials include gallium arsenide (GaAs) and other Group III-V semiconductor material systems, and both single crystal silicon (c-Si) and polycrystalline silicon (mc-Si). These materials are used in the form of thin, brittle wafers and thus require protection against deflection and breakage, usually by the presence of a cover plate. Thin film coating materials include, but are not limited to, copper indium diselenide (CIS), copper indium gallium diselenide (CIGS), cadmium telluride (CdTe) and amorphous silicon (a-Si). Use of these materials also requires the presence of a cover plate; the cover plate may also be the substrate for growth of the coating. With the thin film type, glass may act as the substrate for growth of the photovoltaic layers. Organic materials include dye-sensitized cells.

Manufacturers of solar units seek to improve the efficiency of their units, and to reduce manufacturing costs. In the case of photovoltaic solar units, these two objectives are linked through the dollar per watt peak ($/Wp) selling cost. “Watt peak” is the number of watts output when a photovoltaic unit is illuminated with solar radiation corresponding to Air Mass 1.5 at 1000 watts per square metre intensity at 25° C. ambient temperature.

One way of improving unit efficiency is to maximise the radiation transfer through to the photovoltaic/mirror/heat absorbing material. For photovoltaic solar units, solar mirrors and solar thermal systems, the most commonly used measure for specifying the transmission of the cover glass is Direct Solar Heat Transmission (DSHT), also known in the art as Transmitted Energy (TE). DSHT is an integrated transmission value over the wavelength range 300-2500 nm, which encompasses the spectral response ranges of all of the photovoltaic materials described earlier. To maximise transmission in this wavelength range, the cover plate of a photovoltaic unit may incorporate one or more external anti-reflective layers or a three-dimensional pattern to increase the intensity of transmitted radiation compared to a standard pane of glass having neither of these features. Use of one of more external anti-reflective layers is also useful for increasing transmission of IR, UV and visible light in a mirror solar unit.

Furthermore, ideally the cover glass itself should show no absorption over the wavelength region which is utilised by the photovoltaic material, or reflected by the solar mirror, or absorbed by the solar thermal system. In practice this is not possible due to the presence of trace impurities present in even the purest raw glass-making materials. These impurities include iron, cobalt, etc., which occur naturally in the minerals and processed materials used to make glass. The principal colourant of concern is iron and particularly when it is present in the ferrous Fe(II) state. An Fe²⁺ ion gives glass a blue-green colouration, which results from an absorption band with a maximum absorption (i.e. minimum transmission) around 1050 nm, known as the ferrous absorption band.

In order to maximise solar energy transmission, a glass cover plate manufacturer will naturally seek to minimise the concentrations of these colourants by buying raw materials that are as pure as possible. However, these materials may not be readily available, or if so, may not be available at an economically viable price.

An alternative, or additional, approach to the selective purchasing of raw materials is to ensure that as much as feasible of the iron present in the glass is in the oxidised, less strongly absorbing, ferric Fe(III) state, i.e. the amount of iron in the ferrous Fe(II) state is reduced, or at the very least kept constant if other conditions/ingredients are varied. This may be done by providing the necessary oxidising conditions in a glass-making furnace, however this can be difficult to control and/or the desired oxidation state may not be achieved. Alternatively this may be done by addition of one or more oxidising agents, e.g. sodium nitrate, potassium nitrate and/or an oxide of antimony, arsenic, cerium, vanadium, manganese, copper or titanium, to the glass-making ingredients. Unfortunately, some of these oxidising agents are incompatible with commonly used glassmaking processes, for instance antimony oxide cannot be used in the float process as antimony forms an undesirable alloy with the molten tin present in the float bath.

A further means of improving transmission of radiation is through simple application of the Beer-Lambert law: the thinner a piece of glass of a chosen composition is made, the lower its absorption will be. For example, a 4 mm thick piece of glass containing 0.1% by weight of iron (25% of it being in the ferrous state) will have the same absorption as a 2 mm thick piece of glass containing 0.2% by weight of iron (with 25% ferrous). Similarly a 2 mm thick piece of the 0.1% weight iron glass would show half the absorption of its 4 mm thick parent.

Thus the same transmission might be achieved using less pure raw materials or an improvement in transmission gained for the same colourant composition if the thickness of the glass is reduced. However because glass cover plates are typically toughened or semi-toughened (to give them resistance to stone and hail impact over their long lifetimes), reducing their thicknesses to less than 3 mm can prove to be problematic in terms of compatibility with conventional toughening processes, because thin glass is more difficult to toughen.

US patent application US2008/0085827A1 discloses a glass having a high light transmission and neutral colour. The glass includes a low amount of iron coupled with zinc oxide and/or erbium oxide in amounts designed to provide a neutral colour. As noted above, pure or low-iron raw materials are expensive, and this restricts their use in large-scale commercial operations. Furthermore, erbium oxide is also expensive.

It would therefore be desirable to provide alternative means of increasing radiation transfer through a glass cover plate to the solar material of a solar unit, thereby increasing the efficiency of the latter, which does not suffer from the problems associated with other methods.

Accordingly, the present invention provides a solar unit glass plate having a composition comprising the following constituents, the amounts of which are expressed as percentages by weight:

| | |
|---|---|
| SiO₂ | 60-75% |
| Al₂O₃ | 0-5% |
| Na₂O | 10-18% |
| K₂O | 0-5% |
| CaO | >0-11% |
| MgO | 0-5% |
| SO₃ | 0-1% |
| Fe₂O₃ (total iron) | <0.15% |

and one or both of:

| | |
|---|---|
| SrO | 0-15% |
| BaO | 0-15% |

with the proviso that the summed amount of SrO and BaO is greater than 1%.

As used throughout this specification, total iron is expressed as if all iron present were present as ferric oxide (Fe₂O₃), as is known in the art. The ferrous level is determined optically using molecular absorption spectrophotometry.

Glass of such a composition is effective at increasing (and potentially maximising) the efficiency of a solar unit of which it may form a part because of the increased (and potentially maximised) degree of radiation transmitted by it. These increases have been realised because firstly the iron content of the glass is restricted, and secondly the maximum of the ferrous absorption band (discussed earlier) is shifted from the region in which a solar unit operates to longer wavelengths (the longer the better).

Although the principle of ferrous band shift is known in the field of automotive glazings as a means of improving performance (performance being the difference between the visible light transmission (which should be as high as possible) and DSHT (which should be as low as possible) for a given glass thickness), it was surprising to discover that the same type of band shift is of benefit in the manufacture of solar units, particularly the glass component(s), where a high rather than low solar energy transmission is required.

It has been determined, however, that DSHT is not the most effective way to discriminate between glass cover plates for photovoltaic solar units because the DSHT wavelength range is far wider than that utilised by conventional photovoltaic materials, by which it is meant materials that currently collectively operate over the range 400-1100 nm. For the purposes of this specification, a high or low transmission outside this “active” region is of secondary importance to a comparison of different glass cover plates. Thus two different cover glass plates could have the same transmission over the active wavelength range and be used to produce otherwise identical photovoltaic solar units having the same cell efficiency despite having different DSHT values.

For example, consider the following situation. A glass plate A has a high transmission across the full DSHT range (300-2500 nm), whereas a glass plate B, because it has absorption peaks in the 300-400 nm and 1100-2500 nm ranges, has an overall lower DSHT. However both glass plate A and glass plate B give the same cell efficiencies by virtue of them having the same transmission in the active wavelength range (400-1100 nm). Conversely, glass plate C and glass plate D may have the same DSHT values but give different cell efficiencies because one has an absorption band within the 400-1100 nm range whilst the other has equivalent absorption bands outside this wavelength range. For this reason it is believed to be more appropriate to describe photovoltaic solar unit (cover) glass plates using the 400-1100 nm definition of transmission, as is becoming standard in the solar energy industry.

The invention also provides a glass plate for a solar unit, the plate having a composition comprising the following constituents, the amounts of which are expressed as percentages by weight:

| | |
|---|---|
| SiO₂ | 65-74% |
| Al₂O₃ | 0-3% |
| Na₂O | 12-15% |
| K₂O | 0-2% |
| CaO | 0-11% |
| MgO | 0-2% |
| SO₃ | 0-1% |
| Fe₂O₃ (total iron) | <0.1% |

and one or both of:

| | |
|---|---|
| SrO | 2-10% |
| BaO | 1.5-10% |

with the proviso that the summed amount of SrO and BaO is greater than 2%.

The glass plate may be flat (within the meaning of “flat” in general use in the flat glass industry) or curved; any curvature is the result of applying a shaping process to flat glass.

Advantageously, the amount of SrO present in the composition may be between 3 and 8%, preferably between 4 and 6%. The amount of BaO present in the composition may be between 2 and 8%, preferably between 3 and 6%. Typically both strontia and baria will be added to glass-making ingredients as carbonates, both of which are substantially iron-free raw materials, thus contributing to achievement of a low-iron glass.

Satisfaction of these criteria appears useful in generation of the conditions required to make a glass having a transmission, especially in the photovoltaic active wavelength range, that may lead to a higher cell efficiency when the glass is used as a cover plate in a photovoltaic solar unit. For this specification such “high cell efficiency” means at least 0.2, preferably 0.3 percentage points greater than the cell efficiency achieved using a conventional glass cover plate for an otherwise identical photovoltaic solar unit.

Since MgO affects the wavelength at which ferrous iron absorbs, it is preferably present in the composition in an amount less than or equal to 1%, preferably less than or equal to 0.4% and most preferably in as small an amount as possible (less than 0.2%). Ideally, magnesia may be completely absent from the glass composition (not least because the raw material used to incorporate magnesia in a glass composition, dolomite, is difficult to obtain in a low-iron or iron-free form). However in practice this may not be possible, e.g. because of the necessity for reasonably quick transition times from magnesia-containing glass compositions (which may contain up to around 4.5% MgO). A compromise may be reached by inclusion of magnesia at levels of 0.1 to 0.2%, or 0.2 to 0.4%. It appears that reduction of MgO to these low levels, along with the other changes to the glass composition compared to a standard clear glass, contributes to movement of the ferrous absorption band described earlier.

Na₂O (soda) may advantageously be present in an amount less than 16%, preferably less than 15% (around 14% being preferred). Soda is a fluxing agent which is used to promote melting reactions between the batch ingredients, and so is an essential glass-making ingredient.

Preferably, the summed amount of the alkaline earth metal oxide constituents in the composition is in the range 10-20%, preferably 11-18%, most preferably 12-18%.

Advantageously any of the glass compositions described above may be prepared using one or more of the following oxidising agents: nitrates of sodium and potassium and oxides of antimony, arsenic, cerium, manganese, vanadium, copper and titanium. Such materials may be included in the glass composition to promote oxidation of ferrous Fe(II) iron to ferric Fe(III) iron, and so to reduce the intensity of the ferrous absorption band especially in the spectral response region of photovoltaic materials (i.e. the active wavelength range).

The glass may be free of any or all of ZnO, Li₂O, B₂O₃, Er₂O₃ or Sb₂O₃. Some of these materials are expensive, others are incompatible with certain manufacturing processes.

To maintain transmission over longer wavelengths in the 400-1100 nm range, it is desirable that the amount of iron present in the glass in the ferrous Fe(II) state is less than 40%, preferably less than 30 or 25%, most preferably between 15 and 22%.

Advantageously, these measures may result in the maximum of the absorption band due to iron in the ferrous Fe(II) state being positioned between 1120 and 1500 nm, preferably between 1125 and 1400 nm, and most preferably between 1130 and 1300 nm.

For some solar unit applications, e.g. photovoltaic solar units used in architectural design (also known as Building Integrated Photovoltaics (BIPVs)), the cover glass plate may additionally be tinted for aesthetic effect, by incorporation of colourants in the glass-making ingredients. However, such tinting ingredients may reduce the efficiency of the unit, i.e. reduce the efficiency of photovoltaic conversion in BIPVs. This reduction may be mitigated by further alteration and optimisation of the base glass composition, as described herein, however for maximum cell efficiency, the cover glass plate should be as clear as possible.

The glass may be formed by any of the known flat glass forming processes, including in particular the float process and the rolled processes, especially the variant employing twin water-cooled rollers. Especially when manufactured using either the float process or a rolled-glass process, the techniques for which are well-known in the art, a glass plate according to the invention may conveniently be provided in annealed, sheet form. Typically a sheet of glass may be provided in a thickness between 0.5 and 10 mm, preferably between 1 and 5 mm, to balance the mechanical stability afforded with acceptable weight. Said sheets may then be cut to the desired size and further processed as required.

Such further processing may involve toughening or semi-toughening of the glass to impart desired impact resistance characteristics. The ease with which such (semi-) toughening may be done can be judged by the thermal expansion coefficient, α, of the glass. Standard clear glass has α of approximately 90×10⁻⁷° C.⁻¹ between 50 and 350° C., whereas glass according to the invention may have a greater than 100×10⁻⁷° C.⁻¹ between 50 and 350° C., preferably around 102×10⁻⁷° C.⁻¹ between 50 and 350° C. It is believed that the higher the content of soda in a glass composition, the higher the coefficient of thermal expansion of the glass, and the more easily the glass may be toughened. Beneficial toughening characteristics may lead to further production advantages as glass throughput on a toughening line may be increased.

Furthermore it appears that a higher coefficient of thermal expansion may allow for a reduction in the toughening temperature and/or a reduction in the quench pressure used to quench (cool) the hot glass and “fix” the desired compressive and tensile stresses into it. Moreover, a glass plate according to the invention may be satisfactorily toughened or semi-toughened when provided in a thinner thickness (of less than 3.5 mm, or less than 3 mm) using conventional toughening equipment and processes (where specialised equipment is currently required to toughen such thin glasses of standard composition). The thinner the glass plate, the greater the weight reduction that may be achieved, and the greater the radiation transfer through it, which is especially useful for a cover glass plate.

According to a further aspect of the invention there is provided a solar unit comprising at least one glass plate as hereinbefore described. In the case of a photovoltaic solar unit, this at least one glass plate will usually be the cover plate of the unit.

However a photovoltaic solar unit preferably comprises at least two glass plates, each as individually hereinbefore described. In such a case, the glass plates will usually be a cover plate and a backing plate. When the backing plate is made of glass, this will normally be toughened to provide additional mechanical strength at a given thickness. Preferably the backing plate is made of thin glass to reduce the weight of the solar unit.

The solar unit may also be a solar mirror for use in solar energy collection, comprising a curved glass plate which faces the sun. The curvature is selected to suit the focussing effect desired, e.g. it may be parabolic. The mirror may be a second surface mirror. Furthermore, the sun-facing glass plate may constitute a lens for use in solar collection, e.g. a Fresnel lens made by etching the plate.

If both plates are also made thinner than conventional glass plates, the overall weight of a photovoltaic solar unit will be reduced compared to an otherwise identical prior art unit, along with the described efficiency improvements. Weight reduction is likewise very important in solar mirror applications especially where these are mounted on tracking systems which follow the sun's orbit. Many solar thermal systems are mounted on the roofs of buildings. It is advantageous in these systems to reduce the units' weight in order to reduce the structural support required for them.

In a yet further aspect, the invention encompasses the novel glass compositions per se which are disclosed in this specification, regardless of their application.

For a better understanding, the present invention will now be more particularly described by way of non-limiting examples.

Table I below provides examples of glass samples according to the invention along with comparative examples of prior art glasses (Examples 1 & 2), all in 3.2 mm thickness. Example 1 is a known magnesia-containing flat glass composition, while Example 2 is a magnesia-free composition. Table I lists details of the measured compositions, ferrous levels, and position of the maximum of the ferrous absorption band for each composition.

TABLE I

| | | 1 | 2 | 3 | 4 | 5 | 6 | 7 |
|---|---|---|---|---|---|---|---|---|
| SiO₂ | % by | 72.2 | 73.0 | 71.4 | 71.4 | 71.3 | 71.3 | 71.3 |
| Al₂O₃ | weight | 1.1 | 1.6 | 1.1 | 1.1 | 1.1 | 1.1 | 1.1 |
| Fe₂O₃ | | 0.12 | 0.12 | 0.12 | 0.12 | 0.12 | 0.12 | 0.12 |
| Na₂O | | 13.2 | 13.3 | 14.8 | 14.8 | 14.8 | 14.8 | 14.8 |
| K₂O | | 0.7 | 0.7 | 0.7 | 0.7 | 0.7 | 0.7 | 0.7 |
| MgO | | 4.0 | 0.1 | 0.0 | 0.0 | 0.9 | 0.0 | 0.0 |
| CaO | | 8.6 | 11.0 | 8.3 | 4.8 | 5.6 | 4.8 | 4.8 |
| SrO | | 0.0 | 0.0 | 3.5 | 7.0 | 0.0 | 0.0 | 0.0 |
| BaO | | 0.0 | 0.0 | 0.0 | 0.0 | 5.3 | 7.0 | 7.0 |
| SO₃ | | 0.2 | 0.2 | 0.2 | 0.2 | 0.2 | 0.2 | 0.2 |
| Σ Alkali Metal | | 13.9 | 14.0 | 15.4 | 15.4 | 15.4 | 15.4 | 15.4 |
| Oxides | | | | | | | | |
| Σ Alkaline Earth | | 12.5 | 11.1 | 11.8 | 11.8 | 11.8 | 11.8 | 11.8 |
| Metal Oxides | | | | | | | | |
| Ferrous | % | 20 | 20 | 20 | 20 | 20 | 20 | 26 |
| Ferrous band | nm | 1040 | 1115 | 1130 | 1145 | 1115 | 1150 | 1150 |
| maximum | | | | | | | | |
| Change in band | nm | | 75 | 90 | 105 | 75 | 110 | 110 |
| maximum | | | | | | | | |
| from example 1 | | | | | | | | |

Example 1 is a prior art glass containing 0.12% by weight total iron in a typical base glass composition, which notably includes approximately 13% soda, 9% calcia and 4% magnesia, and is devoid of strontia and baria. The ferrous level of this glass is 20% (measured chemically, as described earlier) and the maximum of the ferrous absorption band is located at 1040 nm—a position which interferes with transmission of radiation through to photovoltaic material when the glass is mounted as a cover glass in a photovoltaic unit.

Example 2 illustrates the effect of removing MgO on the ferrous absorption band, producing a modest shift of 75 nm; the MgO has been replaced largely by CaO. Examples 3 to 7 are all glasses illustrative of the invention. These glasses can all be directly compared with Example 1 because they all contain the same amount of total iron as the glass of Example 1. Each of these glasses has its ferrous maximum at a longer wavelength position than that of Example 1; the longest wavelength value being 1150 nm in Examples 6 and 7 (exhibiting a shift of 110 nm).

Analysis of the compositions of the Examples more closely shows that Examples 3 to 7 contain an increased total amount of alkali metal oxide compared to Example 1, which is wholly due to an increased soda level. Furthermore, all contain decreased calcia and magnesia levels compared to Example 1—calcia is decreased by at least 16% whilst magnesia is decreased by at least 29%—both being significant minimum reductions. Moreover, all contain a significant amount of strontia or baria. It should also be noted that the ferrous maximum is shifted to a higher wavelength with each successive addition of baria.

A further refinement to this technique is to weight the transmission spectrum with the cell response of the particular photovoltaic material of interest. In the examples given above the benefit of the change in glass composition compared to a conventional prior art composition was calculated using the following opto-electrical modelling method.

The model is based on a generalised picture of a photovoltaic cell in which light enters the cell through a cover glass, passes through a polymeric interlayer (if appropriate) and then falls on the photovoltaic material itself. In the determination of expected benefits of glass composition changes, the changes to the short-circuit current that arise from changing the transmission through, and/or reflection from, the glass are estimated. To do this, the fraction of incident light that is transmitted to the cell is calculated as a function of wavelength. A weighting factor based on the quantum efficiency (or spectral response) of a particular photovoltaic material is subsequently applied, for example as outlined in chapter two of “Solar Cells—Materials, Manufacture and Operation”, edited by Tom Markvart and Luis Castaner, published by Elsevier 2005. The expected change in the short-circuit current can then be used to estimate a change in the cell efficiency.

As a simple estimate of the beneficial change to glass properties that arises, the transmission of the glass weighted by both the incoming light intensity and the cell response is calculated (summed over all wavelengths). This quantity is subsequently normalised by the light intensity and the cell response, again summed over all wavelengths.

It should be noted that the cell efficiency changes calculated by this method are dependent on the quantum efficiency curves used in the model for the different materials. In each case what are believed to be typical values have been used, however, different manufacturing techniques and material purities may give slightly different results. Thus the calculated benefits are given as examples of what may be achieved rather than as absolutely realisable increases.

Table II shows the relative efficiency improvement predicted for some different types of photovoltaic material with each of the new glass compositions described in Table I above. The illustrative example materials include single crystal silicon wafer (c-Si) and thin film materials—amorphous (a-Si) and polycrystalline (μc-Si) silicon both individually as single junction and combined as a tandem (multiple layer) junction cells, cadmium telluride (CdTe) and copper indium gallium diselenide (CIGS). All data is for samples 3.2 mm in thickness. It should be understood that there may be similar benefits to photovoltaic cells manufactured from other materials e.g. gallium arsenide (GaAs). The benefits for photovoltaic materials which absorb over a spectral range extending further into the infrared are expected to be even greater than for the illustrative examples given here as these materials are more susceptible to the adverse effects of the ferrous absorption band than the illustrative examples given. Similarly, the benefits in concentrator systems utilising mirrors comprising of glass as described in this invention are expected to show a large efficiency benefit over conventional prior art glass as the solar radiation must make a double pass through the glass to the reflective layer and thence to the solar energy collection device.

TABLE II

| | | 1 | 2 | 3 | 4 | 5 | 6 | 7 |
|---|---|---|---|---|---|---|---|---|
| Ferrous | % | 20 | 20 | 20 | 20 | 20 | 20 | 26 |
| DSHT | % | 84.9 | 84.9 | 84.9 | 84.8 | 84.9 | 85.0 | 83.4 |
| (ISO9050 2003, | | | | | | | | |
| AM 1.5) | | | | | | | | |
| Average transmission | % | 84.6 | 84.7 | 84.7 | 84.7 | 84.6 | 84.9 | 83.1 |
| 400-1100 nm | | | | | | | | |
| (no weighting) | | | | | | | | |
| Relative improvement | c-Si | — | 0.3 | 0.1 | 0.3 | 0.2 | 0.5 | −1.0 |
| (in % points) | a-Si | — | 0.2 | 0 | 0.2 | 0.4 | 0.3 | 0.2 |
| over example 1 in | μc-Si | — | 0.4 | 0.2 | 0.5 | 0.3 | 0.7 | −0.9 |
| the Photovoltaic Material | a-Si/μc-Si | — | 0.2 | 0.2 | 0.4 | 0.3 | 0.6 | 0.5 |
| Weighted | tandem | | | | | | | |
| Transmission | CdTe | — | 0.4 | 0.2 | 0.4 | 0.4 | 0.6 | −0.3 |
| | CIGS | — | 0.2 | 0.1 | 0.2 | 0.1 | 0.4 | −1.3 |

Comparing Examples 3 and 4 containing strontia with Example 2, again for the same ferrous level and nominally the same DSHT value, shifting the position of the ferrous band maximum to 1130 or 1145 nm is predicted to result in a further small improvement in the μc-Si and tandem cell performance.

Examples 5, 6 and 7 contain baria. In example 5 the baria is partially substituted for both magnesia and lime and in Examples 6 and 7 the magnesia is completely replaced by baria. Examples 6 and 7 show the largest shift in the position of the ferrous band maximum of 110 nm to 1150 nm as compared with example 1. In particular, comparison of Example 6 with Example 1 shows that, for nominally the same ferrous level and, surprisingly, nominally the same DSHT value, shifting the ferrous band maximum from 1040 nm to 1150 nm results in an improvement of the photovoltaic material weighted transmission of at least 0.3 percentage points, and typically 0.4 to 0.7 percentage points for materials other than a-Si.

To put the benefits of these improvements into context, the typical efficiencies of crystalline silicon wafer based modules are currently (2009) around 15-18% and the thin film modules 6-11%. With a selling price of currently around $4.5/Wp for solar generated power, a relative efficiency improvement of 0.5% could lead to an increase in the module selling price of $1.3-4.1/m2 depending on the photovoltaic material used. The selling price increase depends upon both the photovoltaic material efficiency and the relative change in efficiency generated through the glass composition changes disclosed in this invention. The solar industry is developing rapidly and photovoltaic material efficiencies are likely to increase in the future. Conversely, the selling prices of solar energy is likely to fall. Thus, the overall selling price benefit of improved efficiency generated through these composition changes is expected to remain around this level for some years.

Example 7 illustrates the effect that the ferrous level of a glass has on its PMWT—here the glass has the same composition as the glass in Example 6, but its ferrous level is 26% (compared to 20% in Example 6). The negative values (i.e. worsening) on the PMWT of the glass of Example 7 illustrates that for this glass, the ferrous level is too high. The ferrous level of a glass depends on a number of factors, including the actual composition of each of the raw materials used and the temperature of the glass furnace in which the glass is made, each of which should be managed to keep the ferrous level at an acceptably low level (as described earlier) to achieve the type of benefits shown above in Table II.

The non limiting illustrative examples given above were based on typical clear glass total iron oxide and ferrous levels. The invention herein disclosed also encompasses lower iron oxide and ferrous levels. Table III overleaf shows further illustrative examples with lower total iron levels. As the ferrous absorption is much less significant in low iron content glasses the efficiency benefit on the different solar cell materials of shifting this absorption band to longer wavelengths is consequently much lower in these examples. However, as stated earlier there may be additional benefits such as, but not limited to, availability of low iron strontium or barium containing glass making raw materials in regions of the world in which low iron dolomites are scarce and improved tempering behaviour which might make manufacture of low iron compositions as disclosed in this invention desirable.

TABLE III

| | | 8 | 9 | 10 |
|---|---|---|---|---|
| SiO₂ | % by weight | 71.7 | 73.3 | 71.6 |
| Al₂O₃ | | 1.5 | 1.5 | 1.5 |
| Fe₂O₃ | | 0.025 | 0.025 | 0.025 |
| Na₂O | | 14.1 | 14.0 | 14.8 |
| K₂O | | 0.0 | 0.0 | 0.0 |
| MgO | | 4.0 | 0.1 | 0.1 |
| CaO | | 8.3 | 10.7 | 4.8 |
| SrO | | 0.0 | 0.0 | 0.1 |
| BaO | | 0.0 | 0.0 | 6.7 |
| SO₃ | | 0.3 | 0.3 | 0.3 |
| Σ Alkali Metal Oxides | | 14.1 | 14.1 | 14.8 |
| Σ Alkaline Earth Metal Oxides | | 12.3 | 10.8 | 11.6 |
| Band maximum | nm | 1040 | 1120 | 1130 |
| Change in band maximum | nm | | 80 | 90 |
| from example 8 | | | | |
| Ferrous | % | 15 | 15 | 15 |
| DSHT | % | 90.62 | 90.56 | 90.59 |
| (ISO9050 2003, AM 1.5) | | | | |
| Average transmission 400-1100 nm | % | 90.71 | 90.71 | 90.71 |
| (no weighting) | | | | |
| Relative improvement (in % points) | c-Si | — | 0.02 | 0.05 |
| over example 8 in the | a-Si | — | −0.01 | 0.11 |
| Photovoltaic Material Weighted | μc-Si | — | 0.05 | 0.08 |
| Transmission | a-Si/μc-Si tandem | — | 0.02 | 0.09 |
| | CdTe | — | 0.04 | 0.10 |
| | CIGS | — | 0.01 | 0.02 |

1-20. (canceled)

21. A glass plate for use as a cover plate or backing plate for a solar unit, the plate having a composition comprising the following constituents, the amounts of which are expressed as percentages by weight:

| | |
|---|---|
| SiO₂ | 65-74% |
| Al₂O₃ | 0-3% |
| Na₂O | 12-15% |
| K₂O | 0-2% |
| CaO | 0-11% |
| MgO | 0-2% |
| SO₃ | 0-1% |
| Fe₂O₃ (total iron) | <0.1% |

and one or both of:

| | |
|---|---|
| SrO | 2-10% |
| BaO | 1.5-10% |

with the proviso that the summed amount of SrO and BaO is greater than 2%.

22. The glass plate as claimed in claim 21 wherein SrO is present in the composition in an amount between 3 and 8%.

23. The glass plate as claimed in claim 21 wherein BaO is present in the composition in an amount between 2 and 8%.

24. The glass plate as claimed in claim 21 wherein MgO is present in the composition in an amount less than or equal to 1%.

25. The glass plate as claimed in claim 21 wherein the summed amount of the alkaline earth metal oxide constituents in the composition is in the range 10-20%.

26. The glass plate as claimed in claim 21 wherein the composition is prepared using one or more of the following oxidising agents: sodium nitrate, potassium nitrate and/or oxides of antimony, arsenic, cerium, manganese, vanadium, copper and titanium.

27. The glass plate as claimed in claim 21 wherein the amount of iron present in the glass in the ferrous Fe(II) state is less than 40%.

28. The glass plate as claimed in claim 21 wherein the maximum of the absorption band due to iron in the ferrous Fe(II) state is positioned between 1120 and 1500 nm.

29. The glass plate as claimed in claim 21 which is provided in a thickness of between 0.5 mm and 10 mm.

30. The glass plate as claimed in claim 21 being toughened or semi-toughened.

31. The glass plate as claimed in claim 30 having a thermal expansion coefficient, α, greater than 100×10⁻⁷° C.⁻¹ between 50 and 350° C.

32. The glass plate as claimed in claim 30 which is provided in a thickness less than or equal to 3.5 mm.

33. A solar unit glass plate having a composition comprising the following constituents, the amounts of which are expressed as percentages by weight:

| | |
|---|---|
| SiO₂ | 60-75% |
| Al₂O₃ | 0-5% |
| Na₂O | 10-18% |
| K₂O | 0-5% |
| CaO | 0-11% |
| MgO | 0-5% |
| SO₃ | 0-1% |
| Fe₂O₃ (total iron) | <0.15% |

and one or both of:

| | |
|---|---|
| SrO | 0-15% |
| BaO | 0-15% |

with the proviso that the summed amount of SrO and BaO is greater than 1%.

34. The solar unit glass plate as claimed in claim 33 being toughened or semi-toughened and having a thermal expansion coefficient, α, greater than 100×10⁻⁷° C.⁻¹ between 50 and 350° C.

35. A solar unit comprising a glass cover plate as claimed in claim 21.

36. The solar unit as claimed in claim 35 in the form of a photovoltaic solar unit comprising a glass-cover plate and a glass backing plate, each as individually claimed.

37. The solar unit as claimed in claim 35, in the form of a photovoltaic solar unit, having a cell efficiency at least 0.2 percentage points greater than the cell efficiency achieved using a conventional glass cover plate for an otherwise identical photovoltaic solar unit.

38. A solar mirror for use in solar collection comprising a sun-facing glass plate as claimed in claim 21.

39. The solar mirror as claimed in claim 38 being a second surface mirror.

40. A lens for use in solar collection comprising a sun-facing glass plate as claimed in 21.
